(19) United States
(12) Patent Application Publication
(10) Pub. No.: US 2020/0270479 A1
(43) Pub. Date: Aug. 27, 2020

(54) Shallow Trench Isolation Chemical And Mechanical Polishing Slurry

(71) Applicant: Versum Materials US, LLC, Tempe, AZ (US)

(72) Inventors: Joseph D. Rose, Gilbert, AZ (US); Xiabo Shi, Chandler, AZ (US); Hongjun Zhou, Chandler, AZ (US); Krishna P. Murella, Phoenix, AZ (US)

(73) Assignee: Versum Materials US, LLC, Tempe, AZ (US)

(21) Appl. No.: 16/749,625

(22) Filed: Jan. 22, 2020

Related U.S. Application Data
(60) Provisional application No. 62/810,722, filed on Feb. 26, 2019.

(51) Int. Cl. C09G 1/02; H01L 21/321

(52) U.S. Cl. CPC C09G 1/02; H01L 21/762; H01L 21/3212

(57) ABSTRACT

Shallow Trench Isolation (STI) chemical mechanical planarization (CMP) compositions, methods of using the composition and systems for using the composition are provided. The compositions comprise abrasive particles, and two different groups of chemical additives; a non-ionic organic surfactant molecule including polysorbate-type surfactants formed by the ethoxylation of the sorbitan and non-ionic organic molecules with multi hydroxyl functional groups in the same molecule. The compositions provide high silicon oxide removal rate (RR) and suppressed SiN removal rate (RR). A good pattern performance are provided by the compositions which offer desired silicon oxide RR at a reasonable DF and showing the high SiN RR suppression at an even higher DF from the blanket wafer data.

### CROSS REFERENCE TO RELATED PATENT APPLICATIONS

The application claims the benefit of U.S. application No. 62/810,722 filed on Feb. 26, 2019. The disclosure of application No. 62/798,638 is hereby incorporated by reference.

### BACKGROUND OF THE INVENTION

This invention relates to the Shallow Trench Isolation (STI) chemical mechanical planarization (CMP) compositions and chemical mechanical planarization methods (CMP) for Shallow Trench Isolation (STI) process.

In the fabrication of microelectronics devices, an important step involved is polishing, especially surfaces for chemical-mechanical polishing for recovering a selected material and/or planarizing the structure.

For example, a SiN layer is deposited under a SiO₂ layer to serve as a polish stop layer. The role of such polish stop is particularly important in Shallow Trench Isolation (STI) structures. Selectivity is characteristically expressed as the ratio of the silicon dioxide (silicon oxide for short) polish rate to the nitride polish rate. An example is an increased polishing selectivity rate of silicon dioxide (SiO₂) as compared to silicon nitride (SiN).

In the global planarization of patterned STI structures, reducing SiN film removal rates and reducing oxide trench dishing are two key factors to be considered. The lower trench oxide loss will prevent electrical current leaking between adjacent transistors. Non-uniform trench oxide loss across die (within Die) will affect transistor performance and device fabrication yields. Severe trench oxide loss (high oxide trench dishing) will cause poor isolation of transistor resulting in device failure. Therefore, it is important to reduce trench oxide loss by reducing oxide trench dishing in STI CMP polishing compositions.

U.S. Pat. No. 5,876,490 discloses the polishing compositions containing abrasive particles and exhibiting normal stress effects. The slurry further contains non-polishing particles resulting in reduced polishing rate at recesses, while the abrasive particles maintain high polish rates at elevations. This leads to improved planarization. More specifically, the slurry comprises cerium oxide particles and polymeric electrolyte, and can be used for Shallow Trench Isolation (STI) polishing applications.

U.S. Pat. No. 6,964,923 teaches the polishing compositions containing cerium oxide particles and polymeric electrolyte for Shallow Trench Isolation (STI) polishing applications. Polymeric electrolyte being used includes the salts of polyacrylic acid, similar as those in U.S. Pat. No. 5,876,490. Ceria, alumina, silica & zirconia are used as abrasives. Molecular weight for such listed polyelectrolyte is from 300 to 20,000, but in overall, <100,000.

U.S. Pat. No. 6,616,514 discloses a chemical mechanical polishing slurry for use in removing a first substance from a surface of an article in preference to silicon nitride by chemical mechanical polishing. The chemical mechanical polishing slurry according to the invention includes an abrasive, an aqueous medium, and an organic polyol that does not dissociate protons, said organic polyol including a compound having at least three hydroxyl groups that are not dissociable in the aqueous medium, or a polymer formed from at least one monomer having at least three hydroxyl groups that are not dissociable in the aqueous medium.

U.S. Pat. No. 6,984,588 discloses a chemical mechanical polishing composition comprising a soluble cerium compound at a pH above 3 and a method to selectively polish a silicon oxide overfill in preference to a silicon nitride film layer in a single step during the manufacture of integrated circuits and semiconductors.

U.S. Pat. No. 6,544,892 discloses a method of removing silicon dioxide in preference to silicon nitride from a surface of an article by chemical-mechanical polishing comprising polishing said surface using a polishing pad, water, abrasive particles, and an organic compound having both a carboxylic acid functional group and a second functional group selected from amines and halides.

U.S. Pat. No. 7,247,082 discloses a polishing composition comprising an abrasive, a pH adjusting agent, an improver of a selective ratio, and water, wherein the abrasive is contained in an amount of from 0.5 to 30% by weight, the pH adjusting agent is contained in an amount of from 0.01 to 3% by weight, the improver of a selective ratio is contained in an amount of 0.3 to 30% by weight, and water is contained in an amount of 45 to 99.49% by weight, wherein the weight % is based on the weight of the polishing composition, and wherein the improver is one or more compounds selected from the group consisting of methylamine, ethylamine, propylamine, isopropyl amine, dimethylamine, diethylamine, dipropylamine, diisopropylamine, ethylenediamine, 1,2-diaminopropane, 1,3-propanediamine, 1,4-butanediamine, hexamethylenediamine, N,N,N′,N′-tetramethyl-1,6-diaminohexane, 6-(dimethylamino)-1-hexanol, bis(3-aminopropyl)amine, triethylenetetraamine, diethylene glycol bis(3-aminopropyl) ether, piperazine, and piperidine.”

U.S. Pat. No. 8,778,203 discloses a method for selectively removing a target material on a surface of a substrate, the method comprising the steps of: providing a substrate comprising a target material and a non-target material; dissolving oxygen in a polishing solution to achieve a pre-determined dissolved oxygen concentration, the polishing solution having a pH of from about 5 to about 11, wherein the polishing solution comprises a plurality of abrasive silica particles, at least some of said plurality of abrasive silica particles are functionalized with n-(trimethoxysilylpropyl)isothiouronium chloride; maintaining, by continuously applying substantially pure oxygen to said polishing solution, the pre-determined dissolved oxygen concentration of said polishing solution at or between approximately 8.6 mg/L and approximately 16.6 mg/L; disposing the polishing solution between a polishing pad and the surface; applying the polishing pad to the surface; and selectively removing a predetermined thickness of the target material; wherein varying the dissolved oxygen content of the polishing solution varies the removal ratio of target material to non-target material during the removal step.

U.S. Pat. No. 6,914,001 discloses s chemical mechanical polishing method comprising: contacting a surface of a semiconductor wafer with a surface of a polishing pad; supplying an aqueous solution containing abrasive particles, a removal rate accelerator, and different first and second passivation agents to an interface between the surface of the polishing pad and the surface of the semiconductor wafer, wherein the first passivation agent is an anionic, cationic or nonionic surfactant; and, rotating the surface of the semiconductor wafer relative to the surface of the polishing pad to remove an oxide material on the semiconductor wafer.

However, those prior disclosed Shallow Trench Isolation (STI) polishing compositions did not address the importance of SiN film removal rate suppressing and oxide trench dishing reducing and more uniform oxide trench dishing on the polished patterned wafers along with the high oxide vs nitride selectivity. Also, those prior disclosed Shallow Trench Isolation (STI) polishing compositions did not provide the suitable methods on how to use blanket wafer polishing results to predict patterned wafer polishing performances.

Therefore, it should be readily apparent from the foregoing that there remains a need within the art for compositions, methods and systems of STI chemical mechanical polishing that can afford the reduced SiN film removal rates and the reduced oxide trench dishing and more uniformed oxide trench dishing across various sized oxide trench features on polishing patterned wafers in a STI chemical and mechanical polishing (CMP) process, and that can afford the method for using blanket wafer polishing results to predict patterned wafer polishing performances in addition to high removal rate of silicon dioxide as well as high selectivity for silicon dioxide to silicon nitride.

### SUMMARY OF THE INVENTION

The present invention provides STI CMP polishing slurries or compositions for the suppressed SiN film removal rate and the high TEOS: SiN selectivity and the reduced oxide trench dishing on the polished patterned wafers. In addition, the compositions improve oxide to nitride selectivity by metric for better predicting patterned performance from blanket results.

The present invented STI CMP polishing compositions provides high oxide vs nitride selectivity by introducing chemical additives as SiN film removal rate suppressing agents and oxide trenching dishing reducers in the Chemical mechanical polishing (CMP) compositions for Shallow Trench Isolation (STI) CMP applications at wide pH range including acidic, neutral and alkaline pH conditions.

The disclosed chemical mechanical polishing (CMP) compositions for Shallow Trench Isolation (STI) CMP applications have a unique combination of using ceria-coated inorganic oxide abrasive particles and the suitable chemical additives as oxide trench dishing reducing agents and nitride suppressing agents.

The present invention also provides methods and systems used to polish SiN film at high down force and polish silicon oxide film at relatively low-down force which still affords the desirable silicon oxide film removal rates for actual STI CMP process applications. The methods and systems have been proved to be an effective way to use blanket wafer polishing results to predict the patterned wafer polishing performances while with suitable chemical additives were used as SiN removal rate suppressing agents.

In one aspect, there is provided a STI CMP polishing composition comprises:

ceria-coated inorganic oxide particles;
two chemical additives independent selected from two different groups: non-ionic organic surfactant molecules including polysorbate-type surfactants formed by the ethoxylation of the sorbitan and non-ionic organic molecules with multi hydroxyl functional groups in the same molecule;
a water-soluble solvent; and
optionally
biocide; and
pH adjuster;
wherein the composition has a pH of 2 to 12, preferably 3 to 10, more preferably 4 to 9, and most preferably 4.5 to 7.5.

The ceria-coated inorganic oxide particles include, but are not limited to, ceria-coated colloidal silica, ceria-coated alumina, ceria-coated titania, ceria-coated zirconia, or any other ceria-coated inorganic oxide particles.

The water-soluble solvent includes but is not limited to deionized (DI) water, distilled water, and alcoholic organic solvents.

The chemical additives function as a SiN film removal rate suppressing agent and oxide trenching dishing reducer.

The first group of chemical additives are non-ionic organic surfactant molecules including polysorbate-type surfactants formed by the ethoxylation of the sorbitan.

Some examples of the first group chemical additives included, but are not limited to: polyoxyethylenesorbitan monolaurate, polyoxyethylenesorbitan monopalmitate, polyoxyethylene sorbitan monostearate, polyoxyethylenesorbitan tristearate, Polyoxyethylenesorbitan monooleate, polyoxyethylenesorbitan trioleate and others.

The second group of chemical additives are non-ionic organic molecules with multi hydroxyl functional groups in the same molecule.

The second group of chemical additive include but are not limited to the non-ionic organic molecules having the following structures.

In one embodiment, the second group of chemical additive has a general structure (a) is shown below:

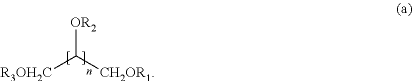

n is selected from 2 to 5,000, preferably from 3 to 12, and more preferably from 4 to 6.

R1, R2, and R3 groups can be the same or different atoms or functional groups.

R1, R2, and R3 can be independently selected from the group consisting of hydrogen, an alkyl group CmH2m₊1, m is from 1 to 12, preferably 1 to 6, and more preferably 1 to 3; alkoxy; organic group with one or more hydroxyl groups; substituted organic sulfonic acid; substituted organic sulfonic acid salt; substituted organic carboxylic acid; substituted organic carboxylic acid salt; organic carboxylic ester; organic amine groups; and combinations thereof; wherein, at least two or more of R groups are hydrogen atoms.

In another embodiment, the second group of chemical additive has a general structure shown below:

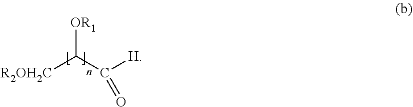

In this structure, one —CHO functional group is located at one end of the molecule as the terminal functional group; n is selected from 2 to 5,000, from 3 to 12, preferably from 4 to 7.

Each of R1 and R2 can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof.

In yet another embodiment, the chemical additives of the second group has a molecular structure selected from the group comprising of (c), (d), (e) and combinations thereof:

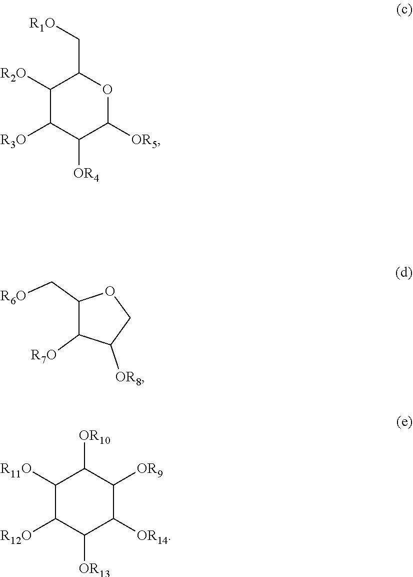

In these general molecular structures; R₁, R₂, R₃, R₄, R₅, R₆, R₇, R₈, R₉, R₁₀, R₁₁, R₁₂, R₁₃, and R₁₄ can be the same or different atoms or functional groups.

Each of the R group can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof; wherein, at least two or more of R groups are hydrogen atoms.

For structures (c) and (e), preferably four or more of R groups are hydrogen atoms.

Yet, in another embodiment, the chemical additives of the second group of has a general molecular structure (f)

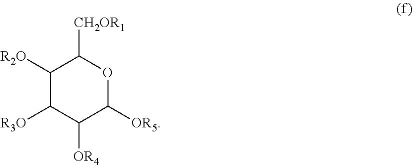

The general molecular structure (f) has at least two, or at least four Rs in the group of R1 to R5 are hydrogen atoms. Thus, the chemical additives (f) contain at least two, or at least four hydroxyl functional groups in the molecular structures.

In structure (f), at least one R in the groups of R1 to R5 in the general molecular structure (f) is a polyol molecular unit having a structure shown in (i):

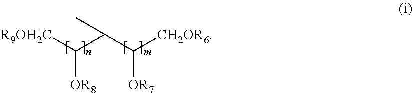

n and m can be the same or different. m or n is independently selected from 1 to 5, preferably from 1 to 4, more preferably from 1 to 3, and most preferably from 1 to 2.

R₆ to R₉ can be the same or different atoms or functional groups; each of R₆, R₇, R₈, and R₉ is independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine, and combinations thereof, and at least two of R groups are hydrogen atoms.

Each of the rest of Rs in the group of R1 to R5 in (f) can be independently selected from the group consisting of hydrogen, alkyl, alkoxy, organic group with one or more hydroxyl groups, substituted organic sulfonic acid or salt, substituted organic carboxylic acid or salt, organic carboxylic ester, organic amine, a six-member ring polyol having a structure shown in (ii):

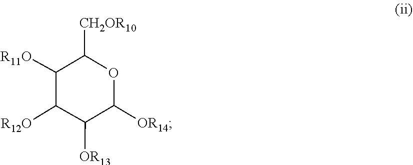

wherein the structure (ii) is connected through oxygen carbon bond to structure (f) by removing one R from R₁₁ to R₁₄ in (ii) and each of the rest R₁₀ to R₁₄ is independently selected from the group consisting of hydrogen, alkyl, alkoxy, organic group with one or more hydroxyl groups, substituted organic sulfonic acid or salt, substituted organic carboxylic acid or salt, organic carboxylic ester, organic amine, and combinations thereof.

Examples of the second group of chemical additives comprise maltitol, lactitol, maltotritol, ribitol, D-sorbitol, mannitol, dulcitol, iditol, D-(−)-Fructose, sorbitan, sucrose, ribose, Inositol, glucose, D-arabinose, L-arabinose, D-mannose, L-mannose, meso-erythritol, beta-lactose, arabinose, and combinations thereof. The preferred chemical additives are maltitol, lactitol, maltotritol, D-sorbitol, mannitol, dulcitol, iditol, D-(−)-Fructose, sucrose, ribose, Inositol, glucose. D-(+)-mannose, beta-lactose, and combinations thereof. The more preferred chemical additives are maltitol, lactitol, maltotritol, D-sorbitol, mannitol, dulcitol, D-(−)-Fructose, beta-lactose, and combinations thereof.

The molecular structures of some examples of the second group of chemical additives are listed below:

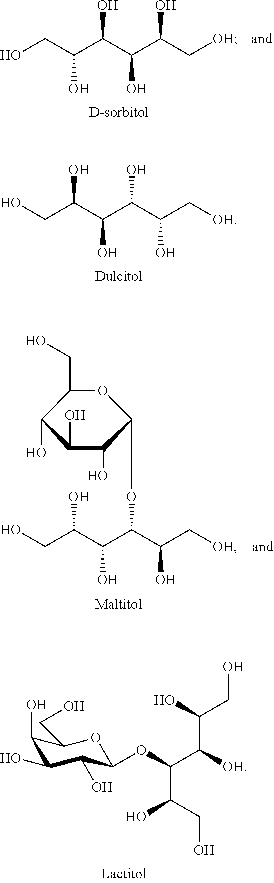

In another aspect, there is provided a method of chemical mechanical polishing (CMP) a substrate having at least one surface comprising silicon dioxide using the chemical mechanical polishing (CMP) composition described above in Shallow Trench Isolation (STI) process.

In another aspect, there is provided a system of chemical mechanical polishing (CMP) a substrate having at least one surface comprising silicon dioxide using the chemical mechanical polishing (CMP) composition described above in Shallow Trench Isolation (STI) process.

The polished silicon oxide films can be Chemical vapor deposition (CVD), Plasma Enhance CVD (PECVD), High Density Deposition CVD(HDP), or spin on silicon oxide films.

The substrate disclosed above can further comprises a silicon nitride surface. The removal selectivity of SiO₂: SiN is greater than silicon nitride is greater than 30, preferably greater than 50, and more preferably greater than 70.

In yet another aspect, there is provided a method of predicating patterned wafer polishing performance of a chemical mechanical polishing composition, comprising
determining down force Down Force 1 (DF1) (psi) for obtaining 2000 Å/min. oxide blanket wafer removal rate using the CMP composition;
determining silicon nitride blanket wafer removal rate at a down force of DF1+3.0 psi using the CMP composition;
calculating a DF Offset Selectivity of oxide: silicon nitride films;
selecting the chemical additives having DF Offset Selectivity ≥25, preferably ≥35 or more preferably ≥45;
wherein the DF Offset Selectivity=2000 Å/min./SiN Removal Rate (RR) (Å/min) at DF1+3 psi.

### DETAILED DESCRIPTION OF THE INVENTION

In the global planarization of patterned STI structures, suppressing SiN removal rates and reducing oxide trench dishing across various sized oxide trench features are key factors to be considered.

The lower trench oxide loss will prevent electrical current leaking between adjacent transistors. Non-uniform trench oxide loss across die (within Die) will affect transistor performance and device fabrication yields. Severe trench oxide loss (high oxide trench dishing) will cause poor isolation of transistor resulting in device failure. Therefore, it is important to reduce trench oxide loss by reducing oxide trench dishing in STI CMP polishing compositions.

This invention relates to the Chemical mechanical polishing (CMP) compositions for Shallow Trench Isolation (STI) CMP applications.

More specifically, the disclosed chemical mechanical polishing (CMP) composition for Shallow Trench Isolation (STI) CMP applications have a unique combination of using ceria-coated inorganic oxide abrasive particles and the suitable two groups of chemical additives as oxide trench dishing reducing agents and nitride removal rate suppressing agents.

The first group of chemical additives are non-ionic organic surfactant molecules including polysorbate-type surfactants formed by the ethoxylation of the sorbitan, etc.

The ethoxylate unit repeating numbers in the first group additives can be varied which will provide different HLB values and different solubility in deionized water.

Depending on the lengths of the repeating ethoxylate units, Tween® type of the organic surfactants provided by Millipore Sigma are considered and used as first group of chemical additives.

The second group of chemical additives include but are not limited to the organic molecules which bearing multi hydroxyl functional groups on the same molecules.

The second group of chemical additives are non-ionic molecules which bearing two or more hydroxyl functional groups in the same molecules.

The use of both chemical additives in the STI CMP polishing compositions provides the benefits of high silicon oxide film removal rates, low SiN film removal rates, high and tunable Silicon oxide: SiN selectivity, and reduced oxide trench dishing and improved over polishing window stability on polishing patterned wafers.

In one aspect, there is provided a STI CMP polishing composition comprises:

ceria-coated inorganic oxide particles;
two chemical additives independent selected from two different groups: non-ionic organic surfactant molecules including polysorbate-type surfactants formed by the ethoxylation of the sorbitan; and non-ionic organic molecules with multi hydroxyl functional groups in the same molecule;
a water-soluble solvent; and
optionally
biocide; and
pH adjuster;
wherein the composition has a pH of 2 to 12, preferably 3 to 10, more preferably 4 to 9, and most preferably 4.5 to 7.5.

The ceria-coated inorganic oxide particles include, but are not limited to, ceria-coated colloidal silica, ceria-coated alumina, ceria-coated titania, ceria-coated zirconia, or any other ceria-coated inorganic oxide particles.

The particle sizes of these ceria-coated inorganic oxide particles in the disclosed invention herein are ranged from 10 nm to 1,000 nm, the preferred mean particle sized are ranged from 20 nm to 500 nm, the more preferred mean particle sizes are ranged from 50 nm to 250 nm.

The concentrations of these ceria-coated inorganic oxide particles range from 0.01 wt. % to 20 wt. %, the preferred concentrations range from 0.05 wt. % to 10 wt. %, the more preferred concentrations range from 0.1 wt. % to 5 wt. %.

The preferred ceria-coated inorganic oxide particles are ceria-coated colloidal silica particles.

The water-soluble solvent includes but is not limited to deionized (DI) water, distilled water, and alcoholic organic solvents.

The preferred water-soluble solvent is DI water.

The STI CMP composition may contain biocide ranging from 0.0001 wt. % to 0.05 wt. %; preferably from 0.0005 wt. % to 0.025 wt. %, and more preferably from 0.001 wt. % to 0.01 wt. %.

The biocide includes, but is not limited to, Kathon™, Kathon™ CG/ICP II, from Dupont/Dow Chemical Co. Bioban from Dupont/Dow Chemical Co. They have active ingredients of 5-chloro-2-methyl-4-isothiazolin-3-one and 2-methyl-4-isothiazolin-3-one.

The STI CMP composition contains 0 wt. % to 1 wt. %; preferably 0.01 wt. % to 0.5 wt. %; more preferably 0.1 wt. % to 0.25 wt. % pH adjusting agent.

An acidic or basic pH adjusting agent can be used to adjust the STI polishing compositions to the optimized pH value.

The pH adjusting agents include, but are not limited to nitric acid, hydrochloric acid, sulfuric acid, phosphoric acid, other inorganic or organic acids, and mixtures thereof.

pH adjusting agents also include the basic pH adjusting agents, such as sodium hydride, potassium hydroxide, ammonium hydroxide, tetraalkyl ammonium hydroxide, organic quaternary ammonium hydroxide compounds, organic amines, and other chemical reagents that can be used to adjust pH towards the more alkaline direction.

Depending on the lengths of the repeating ethoxylate units, the first group of chemical additives include but not limited to: polyoxyethylenesorbitan monolaurate, polyoxyethylenesorbitan monopalmitate, polyoxyethylene sorbitan monostearate, polyoxyethylenesorbitan tristearate, Polyoxyethylenesorbitan monooleate, polyoxyethylenesorbitan trioleate and others.

The ethoxylate unit repeating numbers in the first group additives can be varied which will provide different HLB values and different solubility in deionized water.

Tween® type of the organic surfactants provided by Millipore Sigma; such as Tween° 20 (Polyoxyethylene sorbitan monolaurate), Tween° 40 (Polyoxyethylene sorbitan monopalmitate), Tween° 60 (Polyoxyethylene sorbitan monostearate), Tween° 65 (polyoxyethylenesorbitan tristearate), Tween° 80 (Polyoxyethylene sorbitan monooleate), and Tween® 85 (polyoxyethylenesorbitan trioleate) are considered and used as first group of chemical additives in the STI CMP polishing compositions.

The second group of chemical additive include but are not limited to the following structures and the combinations.

In one embodiment, the second group of chemical additive has a general structure (a) as shown below:

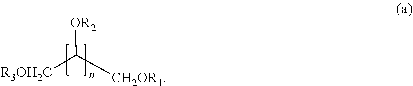

n is selected from 2 to 5,000, preferably from 3 to 12, and more preferably from 4 to 6.

R1, R2, and R3 groups can be the same or different atoms or functional groups. And at least two of the R groups are hydrogen atoms

R1, R2, and R3 can be independently selected from the group consisting of hydrogen, an alkyl group CₘH₂ₘ₊₁, m is from 1 to 12, preferably 1 to 6, and more preferably 1 to 3; alkoxy; organic group with one or more hydroxyl groups; substituted organic sulfonic acid; substituted organic sulfonic acid salt; substituted organic carboxylic acid; substituted organic carboxylic acid salt; organic carboxylic ester; organic amine groups; and combinations thereof.

In another embodiment, the second group of chemical additive has a general structure as shown below:

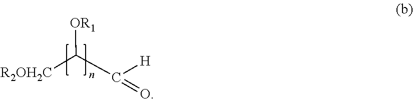

In this structure, one -CHO functional group is located at one end of the molecule as the terminal functional group; n is selected from 2 to 5,000, from 3 to 12, preferably from 4 to 7.

Each of R1 and R2 can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof.

In yet another embodiment, the chemical additives of the second group of has a molecular structure selected from the group comprising of (c), (d), (e) and combinations thereof:

In these general molecular structures; R₁, R₂, R₃, R₄, R₅, R₆, R₇, R₈, R₉, R₁₀, R₁₁, R₁₂, R₁₃, and R₁₄ can be the same or different atoms or functional groups.

Each of the R group can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof; wherein, at least two or more of R groups are hydrogen atoms.

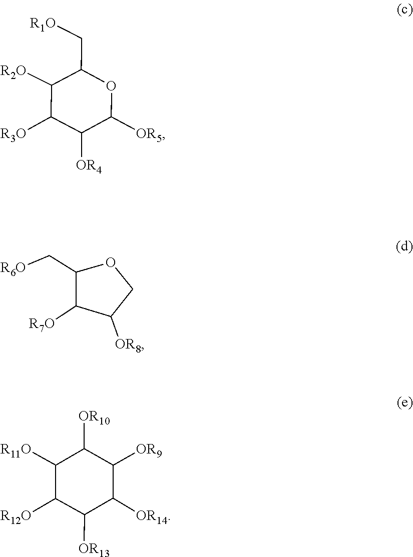

For structures (c) and (e), preferably four or more of R groups are hydrogen atoms.

Yet, in another embodiment, the chemical additives of the second group of has a general molecular structure (f)

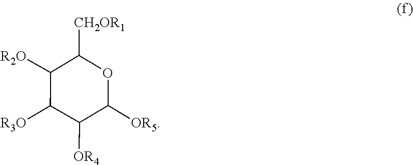

The general molecular structure (f) has at least two, or at least four Rs in the group of R1 to R5 are hydrogen atoms. Thus, the chemical additives (f) contain at least two, or at least four hydroxyl functional groups in the molecular structures.

In structure (f), at least one R in the groups of R1 to R5 in the general molecular structure (f) is a polyol molecular unit having a structure shown in (i):

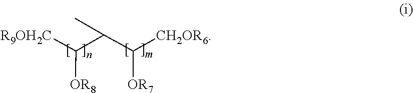

n and m can be the same or different. m or n is independently selected from 1 to 5, preferably from 1 to 4, more preferably from 1 to 3, and most preferably from 1 to 2.

R₆ to R₉ can be the same or different atoms or functional groups; each of R₆, R₇, R₈, and R₉ is independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine, and combinations thereof, and at least two of R groups are hydrogen atoms.

Each of the rest of Rs in the group of R1 to R5 in (f) can be independently selected from the group consisting of hydrogen, alkyl, alkoxy, organic group with one or more hydroxyl groups, substituted organic sulfonic acid or salt, substituted organic carboxylic acid or salt, organic carboxylic ester, organic amine, a six-member ring polyol having a structure shown in (ii):

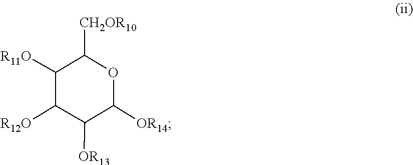

wherein the structure (ii) is connected through oxygen carbon bond to structure (f) by removing one R from R₁₁ to R₁₄ in (ii) and each of the rest R₁₀ to R₁₄ is independently selected from the group consisting of hydrogen, alkyl, alkoxy, organic group with one or more hydroxyl groups, substituted organic sulfonic acid or salt, substituted organic carboxylic acid or salt, organic carboxylic ester, organic amine, and combinations thereof.

The preferred second group of chemical additives contain at least two or more hydroxyl groups in the same non-ionic organic molecules.

Examples of the second group of chemical additives comprise maltitol, lactitol, maltotritol, ribitol, D-sorbitol, mannitol, dulcitol, iditol, D-(−)-Fructose, sorbitan, sucrose, ribose, Inositol, glucose, D-arabinose, L-arabinose, D-mannose, L-mannose, meso-erythritol, beta-lactose, arabinose, and combinations thereof. The preferred chemical additives are maltitol, lactitol, maltotritol, D-sorbitol, mannitol, dulcitol, iditol, D-(−)-Fructose, sucrose, ribose, Inositol, glucose. D-(+)-mannose, beta-lactose, and combinations thereof. The more preferred chemical additives are maltitol, lactitol, maltotritol, D-sorbitol, mannitol, dulcitol, D-(−)-Fructose, beta-lactose, and combinations thereof.

The molecular structures of some examples of the second group of chemical additives are listed below:

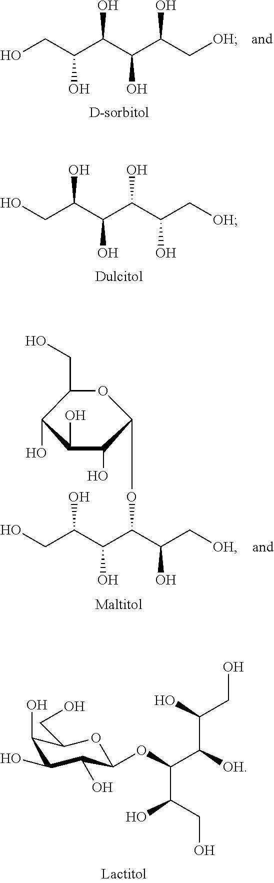

The STI CMP composition contains 0.001 wt. % to 2.0% wt. %, preferably 0.0025 wt. % to 1.0 wt. %, and more preferable 0.05 wt. % to 0.5 wt. % of the second group of chemical additives.

In another aspect, there is provided a method of chemical mechanical polishing (CMP) a substrate having at least one surface comprising silicon dioxide using the chemical mechanical polishing (CMP) composition described above in Shallow Trench Isolation (STI) process.

In another aspect, there is provided a system of chemical mechanical polishing (CMP) a substrate having at least one surface comprising silicon dioxide using the chemical mechanical polishing (CMP) composition described above in Shallow Trench Isolation (STI) process.

The polished oxide films can be Chemical vapor deposition (CVD), Plasma Enhance CVD (PECVD), High Density Deposition CVD (HDP), or spin on oxide films.

The substrate disclosed above can further comprises a silicon nitride surface. The removal selectivity of SiO₂: SiN is greater than 30, preferably greater than 50, and more preferably greater than 70.

In another aspect, there is provided a method of chemical mechanical polishing (CMP) a substrate having at least one surface comprising silicon dioxide using the chemical mechanical polishing (CMP) composition described above in Shallow Trench Isolation (STI) process. The polished oxide films can be CVD oxide, PECVD oxide, High density oxide, or Spin on oxide films.

Silicon oxide to silicon nitride blanket wafer removal rate selectivity is important screening criteria for selecting a chemical and mechanical polishing (CMP) slurry for Shallow Trench Isolation (STI) application. Blanket wafer selectivity is typically defined as Silicon oxide RR/Silicon nitride (SiN) RR at the same Down Force (DF).

However, good blanket wafer selectivity does not always guarantee desired pattern wafer performance. For example, during pattern wafer polish, as topography changes during over-polish due to dishing, the exposed SiN areas may experience higher DF than the polishing pressure due to localized pressure change.

Thus, if a CMP polishing composition having a chemical additive that suppresses SiN blanket wafer RR at a DF higher than the applied polishing pressure for polishing patterned wafer, a good polishing pattern performance can be achieved. Meanwhile, CMP polishing composition must also maintain high silicon oxide RR in addition to suppressing SiN RR.

A down force (DF) Offset blanket wafer Selectivity method has been developed and applied to predict polishing performances on polishing patterned wafers.

In present invention, chemical additives are screened for ability to suppress silicon nitride (SiN) blanket wafer RR at a higher DF than would be used in actual STI CMP process, i.e., pattern wafer polishing.

In general, there is always a give silicon oxide film removal rate target with the specific selected and used consumable parts, such as polishing pad and conditioning disk and under the selected polishing recipe setup, such as applied down force, table/head rotating speeds, slurry flow rate (mL/min.) etc.

In current application, a DF called DF1 to achieve 2,000 Å/min silicon oxide RR is first determined from a testing procedure. This 2,000 Å/min removal rate is a typical RR required for many STI applications.

Next, SiN RR at 3.0 psi higher than DF1 is measured.

A “DF Offset Selectivity” is defined as
DF Offset Selectivity=2000 Å/min./SiN RR (Å/min) at DF1+3 psi.

By this metric, Tween® chemical additives have shown the best selectivity by maintaining the desired silicon oxide RR at a reasonable DF and showing the greatest SiN RR suppression at an even higher DF, of all slurries tested.

In yet another aspect, there is provided a method of predicating patterned wafer polishing performance of a chemical mechanical polishing composition, comprising
determining down force DF1 (psi) for obtaining 2000 Å/min silicon oxide blanket wafer removal rate using the CMP composition;
determining silicon nitride blanket wafer removal rate at a down force of DF1+3.0 psi using the CMP composition;
calculating a DF Offset Selectivity of silicon oxide: silicon nitride films;
selecting the chemical additives having DF Offset Selectivity ≥25, preferably ≥35, or more preferably 45;
wherein the DF Offset Selectivity=2000 Å/min/SiN RR (Å/min.) at DF1+3 psi.

The following non-limiting examples are presented to further illustrate the present invention.

### CMP Methodology

In the examples presented below, CMP experiments were run using the procedures and experimental conditions given below.

### Glossary

### Components

Ceria-coated Silica: used as abrasive having a particle size of approximately 100 nanometers (nm); such ceria-coated silica particles can have a particle size of ranged from approximately 20 nanometers (nm) to 500 nanometers (nm);

Ceria-coated Silica particles (with varied sizes) were supplied by JGC Inc. in Japan.

Chemical additives, such as different Tween® type organic surfactants were supplied by Millipore Sigma, St. Louis, Mo.; while maltitol, D-Fructose, Dulcitol, D-sorbitol and other chemical raw materials were also supplied by Millipore Sigma-Aldrich, St. Louis, Mo.

TEOS: tetraethyl orthosilicate

Polishing Pad: Polishing pad, IK4250UH, IC1010-R32 and other pads were used during CMP, supplied by DOW, Inc.

Conditioning Disk: 3M A122 Disk was used which was provided by 3M company.

### Parameters

### General

Å or A: angstrom(s)—a unit of length

BP: back pressure, in psi units

CMP: chemical mechanical planarization=chemical mechanical polishing

CS: carrier speed

DF: Down force: pressure applied during CMP, units psi

min: minute(s)

ml: milliliter(s)

mV: millivolt(s)

psi: pounds per square inch

PS: platen rotational speed of polishing tool, in rpm (revolution(s) per minute)

SF: composition flow, ml/min

Wt. %: weight percentage (of a listed component)

TEOS: SiN Selectivity: (removal rate of TEOS)/(removal rate of SiN)

HDP: high density plasma deposited TEOS

TEOS or HDP Removal Rates: Measured TEOS or HDP removal rate at a given down pressure. The down pressure of the CMP tool was 1.0, 2.0 or 3.0 psi in the examples listed.

SiN Removal Rates: Measured SiN removal rate at a given down pressure. The down pressure of the CMP tool was 3.0, 4.0, or 5.0 psi in the examples listed.

### Metrology

Films were measured with a ResMap CDE, model 168, manufactured by Creative Design Engineering, Inc, 20565 Alves Dr., Cupertino, Calif., 95014. The ResMap tool is a four-point probe sheet resistance tool. Forty-nine-point diameter scan at 5 mm edge exclusion for film was taken.

### CMP Tool

The CMP tool that was used is a 200 mm Mirra, or 300mm Reflexion manufactured by Applied Materials, 3050 Boweres Avenue, Santa Clara, Calif., 95054. An IC1000 pad supplied by DOW, Inc, 451 Bellevue Rd., Newark, Del. 19713 was used on platen 1 for blanket and pattern wafer studies.

The IK4250UH pad or other pad was broken in by conditioning the pad for 18 mins. At 7 lbs. down force on the conditioner. To qualify the tool settings and the pad break-in two tungsten monitors and two TEOS monitors were polished with Versum® STI2305 composition, supplied by Versum Materials Inc. at baseline conditions.

### Wafers

Polishing experiments were conducted using PECVD or LPCVD or HD TEOS wafers. These blanket wafers were purchased from Silicon Valley Microelectronics, 2985 Kifer Rd., Santa Clara, Calif. 95051.

### Polishing Experiments

In blanket wafer studies, silicon oxide blanket wafers, and SiN blanket wafers were polished at baseline conditions. The tool baseline conditions were: table speed; 87 rpm, head speed: 93 rpm, membrane pressure; 1.0 psi, 2.0 psi, 3.0 psi, 4.0 psi or 5.0 psi DF, composition flow; 200 ml/min. The polishing pad used for testing was IK4250UH or IC1010-R32 pad which was supplied by Dow Chemicals.

Deionized water was used as the solvent in the compositions in the working examples.

The patterned wafers (MIT860), supplied by SWK Associates, Inc. 2920 Scott Blvd. Santa Clara, Calif. 95054). These wafers were measured on the Veeco VX300 profiler/AFM instrument. The 3 different sized pitch structures were used for silicon oxide dishing measurement. The wafer was measured at center, middle, and edge die positions.

TEOS: SiN or HDP: SiN Selectivity: (removal rate of TEOS) or HDP/(removal rate of SiN) obtained from the STI CMP polishing compositions were tunable.

### Working Examples

In the following working examples, a STI polishing composition comprising 0.2 wt. % cerium-coated silica particles, 0.28 wt. % maltitol, a biocide ranging from 0.0001 wt. % to 0.05 wt. %, and deionized water at pH 5.35 was prepared as reference (ref.) 1. There was no first group of additive used in Ref. 1.

A STI polishing composition comprising 0.2 wt. % cerium-coated silica particles, 0.025 wt. % Tween® 20, a biocide ranging from 0.001 wt. % to 0.01 wt. %, and deionized water at pH 5.35 was prepared as reference (ref.) 2. There was no second group of additive used in Ref. 2.

The working polishing compositions (or working samples) were prepared with reference 1 (0.2 wt. % cerium-coated silica, 0.28 wt. % maltitol, a biocide ranging from 0.0001 wt. % to 0.05 wt. %, and deionized water) and adding a first group of additive such as Tween® type surfactants or other reference non-ionic or anionic organic surfactants or molecules in the concentration range of 0.01 wt. % to 0.025% wt. %. All working polishing compositions were made with pH 5.35.

Other chemical additives being tested included: Polyether Polyol (Tergitol™ L-64 purchased from Dow Chemical.), silicone glycol copolymer surfactant (DABCO® DC 5604 purchased from Evonik Industries.), Octylphenoxypolyethoxyethanol (Nonidet™ P40 Substitute purchased from MilliporeSigma), and polyethylene glycol (PEG) with different molecular weights purchased from MilliporeSigma.

### EXAMPLE 1

In Example 1, the polishing compositions used for silicon oxide polishing were shown in Table 1.

The polishing step conditions used were: Dow's IK4250UH pad at 5 different psi DF with table/head speed at 87/93rpm and ex-situ conditioning. Tween® 20 at 0.025 wt. % was used as only additive in the Ref.2.

All other non-ionic or anionic surfactants or organic molecular additives were used in the concentration range of 0.01 wt. % to 0.025% wt. %.

All reference samples and working samples had same pH values at around 5.35.

The removal rates (RR at Å/min) for different films were tested at different down forces.

The effects of different chemical additives on the film removal rates and HDP: SiN film selectivity were observed and listed in Table 1.

As the results shown in Table 1, the addition of a chemical additive (one of them was the first group of additive Tween® 20) into the polishing compositions of the reference 1, in general, reduced the silicon oxide film removal rates except when used PEG with MW 400.

With Ref. 2 (there was no second group of additive used in Ref. 2), the lowest HDP film removal rate and HDP: SiN selectivity were obtained among all tested references and working samples.

Several chemical compositions having additives such additives included DABCO DC5604 Tween® 20, Nonidet P40 Substitute, and PEG with 8,000 molecular weight gave suppressed SiN film removal rates at three applied down forces, while afforded good silicon oxide film removal rates.

TABLE 1
Effects of Chemical Additives on Film
RR (Å/min.) & HDP:SiN Selectivity

| | | HDP | PECND | HDP@3.0 |
|---|---|---|---|---|
| | DF | RR | SiN RR | psi:SiN@5 psi |
| Compositions | (psi) | (Å/min.) | (Å/min.) | Selectivity |
| 0.2% Ceria-coated | 3 | 4604 | 57 | |
| Silica + 0.28% | 4 | | 89 | |
| Maltitol as Ref. 1 | 5 | | 187 | 25:1 |
| 0.2% Ceria-coated | 3 | 1541 | 53 | |
| Silica + 0.025% | 4 | | 81 | |
| Tween ® 20 as Ref. 2 | 5 | | 258 | 6:1 |
| Ref. 1 + 0.025% Tergitol | 3 | 4085 | 59 | |
| L-64 | 4 | | 77 | |
| | 5 | | 120 | 34:1 |
| Ref. 1 + 0.025% | 3 | 4021 | 42 | |
| DABCO DC5604 | 4 | | 64 | |
| | 5 | | 97 | 41:1 |
| Ref. 1 + 0.025% | 3 | 2929 | 35 | |
| Tween ® 20 | 4 | | 46 | |
| | 5 | | 53 | 55:1 |
| Ref. 1 + 0.02% Nonidit | 3 | 3557 | 43 | |
| P40 Substitute | 4 | | 64 | |
| | 5 | | 123 | 29:1 |
| Ref. 1 + 0.015% PEG | 3 | 2584 | 52 | |
| (MW 8000) | 4 | | 62 | |
| | 5 | | 86 | 30:1 |
| Ref. 1 + 0.015% PEG | 3 | 5697 | 70 | |
| (MW 400) | 4 | | 104 | |
| | 5 | | 176 | 32:1 |

However, the polishing composition having both first and second additives Maltitol and Tween® 20 (Ref. 1+0.025% Tween 20) provided the best performance.

While looking at oxide film and SiN removal rate changes vs the applied down forces of 3 psi, 4 psi to 5 psi DF, the polishing composition having both first and second additives Maltitol and Tween® 20 not only afforded high oxide removal rate at 3.0 psi DF, but also showed very effective SiN removal rate suppressing at all applied higher DF.

In addition, the highest oxide: SiN selectivity at 3.0 psi DF vs 5.0 psi DF at about 55:1 was achieved.

### EXAMPLE 2

In Example 2, the method of using down force (DF) Offset Selectivity on judging the silicon oxide: SiN selectivity to predict the patterned wafer polishing performances was tested.

DF1 for each polishing composition shown in Table 2 was measured when targeted HDP film removal rate of 2,000 Å/min. was reached.

set as a target removal rate with the corresponding applied down force DF1 using different polishing compositions shown in Table 2.

The SiN removal rate for each polishing composition was then measured using the applied down force of DF1 plus 3.0 psi.

The DF Offset Selectivity of Silicon oxide: SiN was then calculated and listed in Table 2; where DF Offset Selectivity=2000 Å/min./SiN RR (Å/min) at DF1+3 psi.

TABLE 2
Down Force (DF) Offset Selectivity of Silicon oxide:SiN

| | “DF Offset |
|---|---|
| Compositions | Selectivity” |
| 0.2% Ceria-coated Silica + 0.28% Maltitol as Ref.1 | 12.8 |
| Ref.1 + 0.025% Tergitol L-64 | 18.2 |
| Ref.1 + 0.025% DABCO DC5604 | 22.5 |
| Ref.1 + 0.025% Tween 20 | 36.2 |
| Ref.1 + 0.02% Nonidit P40 Substitute | 16.1 |
| Ref.1 + 0.015% PEG (MW 8000) | 20.2 |
| Ref.1 + 0.015% PEG (MW 400) | 16.0 |

As the results shown in Table 2, among all tested polishing compositions the polishing composition having both first and second additives Maltitol and Tween® 20 provided the highest “DF Offset Selectivity of Silicon oxide: SiN Films”, predicting a good patterned wafer performance from the second group of affit in combination with Tween® chemical additives.

The embodiments of this invention listed above, including the working examples, are exemplary of numerous embodiments that may be made of this invention. It is contemplated that numerous other configurations of the process may be used, and the materials used in the process may be elected from numerous materials other than those specifically disclosed.

1. A chemical mechanical polishing composition comprising:
ceria-coated inorganic oxide particles;
at least one of polysorbate-type surfactant;
at least one of non-ionic organic molecules having multi hydroxyl functional groups in the same molecule;
water-soluble solvent; and
optionally
biocide; and
pH adjuster;
wherein the composition has a pH selected from the group consisting of 3 to 10, 4 to 9, and 4.5 to 7.5.

2. The chemical mechanical polishing composition of claim 1, wherein
the ceria-coated inorganic oxide particles are selected from the group consisting of ceria-coated colloidal silica, ceria-coated alumina, ceria-coated titania, ceria-coated zirconia particles and combinations thereof; wherein the particles range from the group consisting of 0.01 wt. % to 20 wt. %; 0.05 wt. % to 10 wt. %, and 0.1 wt. % to 5 wt. %; and
the water-soluble solvent is selected from the group consisting of deionized (Dl) water, distilled water, and alcoholic organic solvents.

3. The chemical mechanical polishing composition of claim 1, wherein
the at least one of polysorbate-type surfactant has a concentration selected from the group consisting of 0.0001 wt. % to 2.0% wt. %, 0.001 wt. % to 1.0 wt. %, and 0.002 wt. % to 0.25 wt. %; and
the at least one of non-ionic organic molecules having multi hydroxyl functional groups in the same molecule has a concentration selected from the group consisting of 0.001 wt. % to 2.0% wt. %, 0.0025 wt. % to 1.0 wt. %, and 0.05 wt. % to 0.5 wt. %.

4. The chemical mechanical polishing composition of claim 1, wherein the at least one of polysorbate-type surfactant is selected from the group consisting of polyoxyethylenesorbitan monolaurate, polyoxyethylenesorbitan monopalmitate, polyoxyethylene sorbitan monostearate, polyoxyethylenesorbitan tristearate, Polyoxyethylenesorbitan monooleate, polyoxyethylenesorbitan trioleate, and combinations thereof.

5. The chemical mechanical polishing composition of claim 1, wherein
the non-ionic organic molecules with multi hydroxyl functional groups in the same molecule has a general molecular structure selected from the group consisting of:
(a) 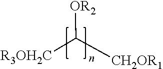
wherein
n is selected from the group consisting of 2 to 5,000, 3 to 12, and 4 to 6;
R1, R2, and R3 groups can be the same or different atoms or functional groups and are independently selected from the group consisting of hydrogen; an alkyl group CmH2m₊1, wherein m is selected from the group consisting of from 1 to 12, 1 to 6, and 1 to 3; alkoxy; organic group with one or more hydroxyl groups; substituted organic sulfonic acid; substituted organic sulfonic acid salt; substituted organic carboxylic acid; substituted organic carboxylic acid salt; organic carboxylic ester; organic amine groups; and combinations thereof; and
at least two groups of R1, R2, and R3 are hydrogen atoms;
(b) 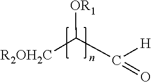
wherein
n is selected from the group consisting of 2 to 5,000, 3 to 12, and 4 to 7; and
each of R1 and R2 can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof;
(c) 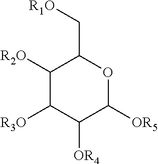
wherein
R₁, R₂, R₃, R₄, and R₅ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₁, R₂, R₃, R₄, and R₅ are hydrogen atoms;
(d) 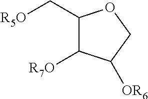
wherein
R₆, R₇, and R₈ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₆, R₇, and R₈ are hydrogen atoms;
(e) 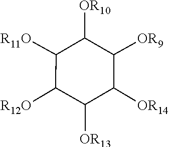
wherein
R₉, R₁₀, R₁₁, R₁₂, R₁₃ and R₁₄ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₉, R₁₀, R₁₁, R₁₂, R₁₃ and R₁₄ are hydrogen atoms;
(f) 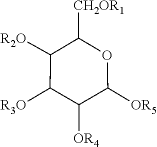
wherein
at least two groups of R1 to R5 are hydrogen atoms;
at least one R of R1 to R5 is a polyol molecular unit having a structure shown in (i): 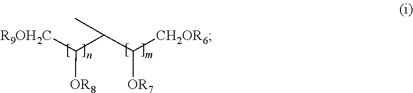
wherein
m or n is independently selected from the group consisting of 1 to 5, 1 to 4, 1 to 3, and 1 to 2;
each of R₆, R₇, R₈, and R₉ is independently selected from the group consisting of hydrogen, alkyl, alkoxy, organic group with at least one hydroxyl groups, substituted organic sulfonic acid, substituted organic sulfonic acid salt, substituted organic carboxylic acid, substituted organic carboxylic acid salt, organic carboxylic ester, organic amine, and combinations thereof; and
at least two groups of R₆, R₇, R₈, and R₉ are hydrogen atoms;
and
rest of each group of R1 to R5 in (f) is independently selected from the group consisting of hydrogen, alkyl, alkoxy, organic group with at least one hydroxyl group, substituted organic sulfonic acid or salt, substituted organic carboxylic acid or salt, organic carboxylic ester, organic amine, and a six-member ring polyol having a structure shown in (ii): 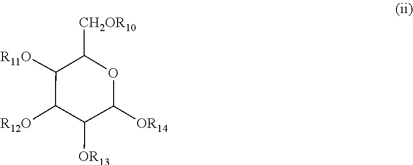
wherein
the structure (ii) is connected through oxygen carbon bond to structure (f) by removing one R from R₁₁ to R₁₄ in (ii);
rest of each group of R₁₀ to R₁₄ is independently selected from the group consisting of hydrogen, alkyl, alkoxy, organic group with at least one hydroxyl group, substituted organic sulfonic acid or salt, substituted organic carboxylic acid or salt, organic carboxylic ester, organic amine, and combinations thereof;
and combinations thereof.

6. The chemical mechanical polishing composition of claim 1, wherein the organic molecules with multi hydroxyl functional groups in the same molecule is selected from the group consisting of maltitol, lactitol, maltotritol, ribitol, D-sorbitol, mannitol, dulcitol, iditol, D-(−)-Fructose, sorbitan, sucrose, ribose, Inositol, glucose, D-arabinose, L-arabinose, D-mannose, L-mannose, meso-erythritol, beta-lactose, arabinose, and combinations thereof.

7. The chemical mechanical polishing composition of claim 1, wherein the organic molecules with multi hydroxyl functional groups in the same molecule is selected from the group consisting of maltitol, lactitol, maltotritol, D-sorbitol, mannitol, dulcitol, D-(−)-Fructose, beta-lactose, and combinations thereof.

8. The chemical mechanical polishing composition of claim 1, wherein the composition comprises ceria-coated colloidal silica particles; the polysorbate-type surfactant selected from the group consisting of polyoxyethylenesorbitan monolaurate, polyoxyethylenesorbitan monopalmitate, polyoxyethylene sorbitan monostearate, polyoxyethylenesorbitan tristearate, polyoxyethylenesorbitan monooleate, polyoxyethylenesorbitan trioleate, and combinations thereof; the organic molecule with multi hydroxyl functional groups in the same molecule selected from the group consisting of D-sorbitol, Dulcitol, Maltitol, Lactitol, and combinations thereof and water.

9. The chemical mechanical polishing composition of claims 1, wherein the composition comprises at least one of
the biocide having active ingredients of 5-chloro-2-methyl-4-isothiazolin-3-one and 2-methyl- -isothiazolin-3-one; and
the pH adjusting agent selected from the group consisting of nitric acid, hydrochloric acid, sulfuric acid, phosphoric acid, other inorganic or organic acids, and mixtures thereof for acidic pH conditions; or selected from the group consisting of sodium hydride, potassium hydroxide, ammonium hydroxide, tetraalkyl ammonium hydroxide, organic quaternary ammonium hydroxide compounds, organic amines, and combinations thereof for alkaline pH conditions.

10. A method of chemical mechanical polishing (CMP) a semiconductor substrate having at least one surface comprising silicon oxide film, comprising
(1) providing the semiconductor substrate;
(2) providing a polishing pad;
(3) providing a chemical mechanical polishing (CMP) composition comprising:
ceria-coated inorganic oxide particles;
at least one of polysorbate-type surfactant;
at least one of non-ionic organic molecules having multi hydroxyl functional groups in the same molecule;
water-soluble solvent; and
optionally
biocide; and
pH adjuster;
wherein
the composition has a pH selected from the group consisting of 2 to 12, 3 to 10, 4 to 9, and 4.5 to 7.5; and
the non-ionic organic molecules with multi hydroxyl functional groups in the same molecule has a general molecular structure selected from the group consisting of:
(a) 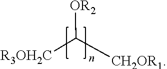
wherein
n is selected from the group consisting of 2 to 5,000, 3 to 12, and 4 to 6;
R1, R2, and R3 groups can be the same or different atoms or functional groups and are independently selected from the group consisting of hydrogen; an alkyl group CmH2m₊1, wherein m is selected from the group consisting of from 1 to 12, 1 to 6, and 1 to 3; alkoxy; organic group with one or more hydroxyl groups; substituted organic sulfonic acid; substituted organic sulfonic acid salt; substituted organic carboxylic acid; substituted organic carboxylic acid salt; organic carboxylic ester; organic amine groups; and combinations thereof; and
at least two groups of R1, R2, and R3 are hydrogen atoms;
(b) 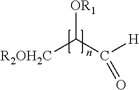
wherein
n is selected from the group consisting of 2 to 5,000, 3 to 12, and 4 to 7; and
each of R1 and R2 can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof;
(c) 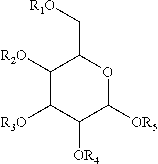
wherein
R₁, R₂, R₃, R₄, and R₅ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₁, R₂, R₃, R₄, and R₅ are hydrogen atoms;
(d) 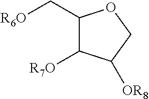
wherein
R₆, R₇, and R₈ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₆, R₇, and R₈, are hydrogen atoms;
(e) 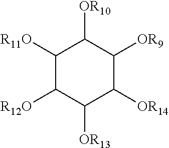
wherein
R₉, R₁₀, R₁₁, R₁₂, R₁₃ and R₁₄ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₉, R₁₀, R₁₁, R₁₂, R₁₃ and R₁₄ are hydrogen atoms;
(f) 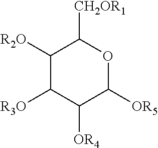
wherein
at least two groups of R₁ to R₅ are hydrogen atoms;
at least one R of R₁ to R₅ is a polyol molecular unit having a structure shown in (i): 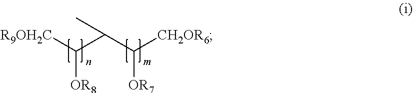
wherein
m or n is independently selected from the group consisting of 1 to 5, 1 to 4, 1 to 3, and 1 to 2;
each of R₆, R₇, R₈, and R₉ is independently selected from the group consisting of hydrogen, alkyl, alkoxy, organic group with at least one hydroxyl groups, substituted organic sulfonic acid, substituted organic sulfonic acid salt, substituted organic carboxylic acid, substituted organic carboxylic acid salt, organic carboxylic ester, organic amine, and combinations thereof; and
at least two groups of R₆, R₇, R₈, and R₉ are hydrogen atoms;
and
rest of each group of R1 to R5 in (f) is independently selected from the group consisting of hydrogen, alkyl, alkoxy, organic group with at least one hydroxyl group, substituted organic sulfonic acid or salt, substituted organic carboxylic acid or salt, organic carboxylic ester, organic amine, and a six-member ring polyol having a structure shown in (ii): 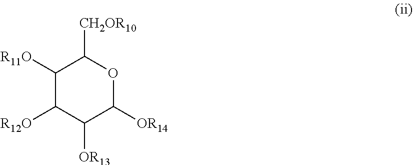
wherein
the structure (ii) is connected through oxygen carbon bond to structure (f) by removing one R from R₁₁ to R₁₄ in (ii);
rest of each group of R₁₀ to R₁₄ is independently selected from the group consisting of hydrogen, alkyl, alkoxy, organic group with at least one hydroxyl group, substituted organic sulfonic acid or salt, substituted organic carboxylic acid or salt, organic carboxylic ester, organic amine, and combinations thereof;
and combinations thereof;
(4) contacting the surface of the semiconductor substrate with the polishing pad and the chemical mechanical polishing composition; and
(5) polishing the least one surface comprising silicon dioxide;
wherein the silicon oxide film is selected from the group consisting of Chemical vapor deposition (CVD), Plasma Enhance CVD (PECVD), High Density Deposition CVD (HDP), or spin on silicon oxide film.

11. The method of claim 10; wherein
the ceria-coated inorganic oxide particles are selected from the group consisting of ceria-coated colloidal silica, ceria-coated alumina, ceria-coated titania, ceria-coated zirconia particles and combinations thereof;
the water-soluble solvent is selected from the group consisting of deionized (DI) water, distilled water, and alcoholic organic solvents;
the at least one of polysorbate-type surfactant is selected from the group consisting of polyoxyethylenesorbitan monolaurate, polyoxyethylenesorbitan monopalmitate, polyoxyethylene sorbitan monostearate, polyoxyethylenesorbitan tristearate, polyoxyethylenesorbitan monooleate, polyoxyethylenesorbitan trioleate, and combinations thereof; and
the organic molecules with multi hydroxyl functional groups in the same molecule is selected from the group consisting of maltitol, lactitol, maltotritol, ribitol, D-sorbitol, mannitol, dulcitol, iditol, D-(−)-Fructose, sorbitan, sucrose, ribose, Inositol, glucose, D-arabinose, L-arabinose, D-mannose, L-mannose, meso-erythritol, beta-lactose, arabinose, and combinations thereof.

12. The method of claim 10; wherein
the chemical mechanical polishing (CMP) composition comprises ceria-coated colloidal silica particles; the polysorbate-type surfactant selected from the group consisting of polyoxyethylenesorbitan monolaurate, polyoxyethylenesorbitan monopalmitate, polyoxyethylene sorbitan monostearate, polyoxyethylenesorbitan tristearate, polyoxyethylenesorbitan monooleate, polyoxyethylenesorbitan trioleate, and combinations thereof; the organic molecule with multi hydroxyl functional groups in the same molecule selected from the group consisting of D-sorbitol, Dulcitol, Maltitol, Lactitol, and combinations thereof; and water; and
the silicon oxide film is SiO₂ film.

13. The method of claim 10; wherein the chemical mechanical polishing (CMP) composition comprises at least one of
the biocide having active ingredients of 5-chloro-2-methyl-4-isothiazolin-3-one and 2-methyl- -isothiazolin-3-one; and
the pH adjusting agent selected from the group consisting of nitric acid, hydrochloric acid, sulfuric acid, phosphoric acid, other inorganic or organic acids, and mixtures thereof for acidic pH conditions; or selected from the group consisting of sodium hydride, potassium hydroxide, ammonium hydroxide, tetraalkyl ammonium hydroxide, organic quaternary ammonium hydroxide compounds, organic amines, and combinations thereof for alkaline pH conditions.

14. The method of claim 10; wherein the semiconductor substrate further comprises a silicon nitride surface; and removal selectivity of silicon oxide: silicon nitride is greater than one selected from the group consisting of 30, 40 and 50.

15. A system of chemical mechanical polishing (CMP) a semiconductor substrate having at least one surface comprising silicon oxide film, comprising
a. the semiconductor substrate;
b. a chemical mechanical polishing (CMP) composition comprising:
ceria-coated inorganic oxide particles;
at least one of polysorbate-type surfactant;
at least one of non-ionic organic molecules having multi hydroxyl functional groups in the same molecule;
water-soluble solvent; and
optionally
biocide; and
pH adjuster;
wherein
the composition has a pH selected from the group consisting of 2 to 12, 3 to 10, 4 to 9, and 4.5 to 7.5; and
the non-ionic organic molecules with multi hydroxyl functional groups in the same molecule has a general molecular structure selected from the group consisting of:
(a) 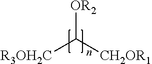
wherein
n is selected from the group consisting of 2 to 5,000, 3 to 12, and 4 to 6;
R1, R2, and R3 groups can be the same or different atoms or functional groups and are independently selected from the group consisting of hydrogen; an alkyl group CmH2m₊1, wherein m is selected from the group consisting of from 1 to 12, 1 to 6, and 1 to 3; alkoxy; organic group with one or more hydroxyl groups; substituted organic sulfonic acid; substituted organic sulfonic acid salt; substituted organic carboxylic acid; substituted organic carboxylic acid salt; organic carboxylic ester; organic amine groups; and combinations thereof; and
at least two groups of R1, R2, and R3 are hydrogen atoms;
(b) 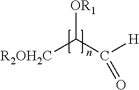
wherein
n is selected from the group consisting of 2 to 5,000, 3 to 12, and 4 to 7; and
each of R1 and R2 can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof;
(c) 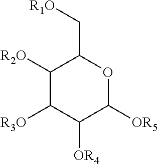
wherein
R₁, R₂, R₃, R₄, and R₅ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₁, R₂, R₃, R₄, and R₅ are hydrogen atoms;
(d) 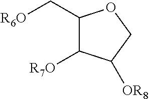
wherein
R₆, R₇, and R₈ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₆, R₇, and R₈ are hydrogen atoms;
(e) 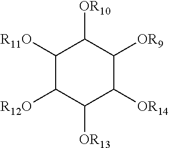
wherein
R₉, R₁₀, R₁₁, R₁₂, R₁₃ and R₁₄ groups are each independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine group, and combinations thereof; and
at least two groups of R₉, R₁₀, R₁₁, R₁₂, R₁₃ and R₁₄ are hydrogen atoms;
(f) 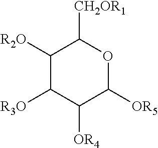
wherein
at least two groups of R1 to R5 are hydrogen atoms;
at least one R of R1 to R5 is a polyol molecular unit having a structure shown in (i): 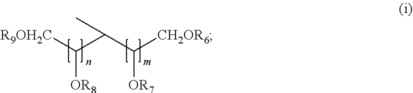
wherein
m or n is independently selected from the group consisting of 1 to 5, 1 to 4, 1 to 3, and 1 to 2;
each of R₆, R₇, R₈, and R₉ is independently selected from the group consisting of hydrogen, alkyl, alkoxy, organic group with at least one hydroxyl groups, substituted organic sulfonic acid, substituted organic sulfonic acid salt, substituted organic carboxylic acid, substituted organic carboxylic acid salt, organic carboxylic ester, organic amine, and combinations thereof; and
at least two groups of R₆, R₇, R₈, and R₉ are hydrogen atoms;
and
rest of each group of R1 to R5 in (f) is independently selected from the group consisting of hydrogen, alkyl, alkoxy, organic group with at least one hydroxyl group, substituted organic sulfonic acid or salt, substituted organic carboxylic acid or salt, organic carboxylic ester, organic amine, and a six-member ring polyol having a structure shown in (ii): 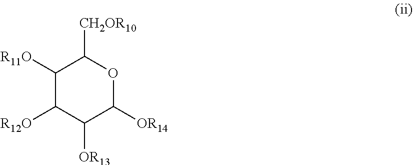
wherein
the structure (ii) is connected through oxygen carbon bond to structure (f) by removing one R from R₁₁ to R₁₄ in (ii);
rest of each group of R₁₀ to R₁₄ is independently selected from the group consisting of hydrogen, alkyl, alkoxy, organic group with at least one hydroxyl group, substituted organic sulfonic acid or salt, substituted organic carboxylic acid or salt, organic carboxylic ester, organic amine, and combinations thereof;
and combinations thereof;
c. a polishing pad;
wherein
the silicon oxide film is selected from the group consisting of Chemical vapor deposition (CVD), Plasma Enhance CVD (PECVD), High Density Deposition CVD (HDP), or spin on silicon oxide film; and
the at least one surface comprising silicon oxide film is in contact with the polishing pad and the chemical mechanical polishing composition.

16. The system of claim 15; wherein
the ceria-coated inorganic oxide particles are selected from the group consisting of ceria-coated colloidal silica, ceria-coated alumina, ceria-coated titania, ceria-coated zirconia particles and combinations thereof;
the water-soluble solvent is selected from the group consisting of deionized (DI) water, distilled water, and alcoholic organic solvents;
the at least one of polysorbate-type surfactant is selected from the group consisting of polyoxyethylenesorbitan monolaurate, polyoxyethylenesorbitan monopalmitate, polyoxyethylene sorbitan monostearate, polyoxyethylenesorbitan tristearate, polyoxyethylenesorbitan monooleate, polyoxyethylenesorbitan trioleate, and combinations thereof; and
the organic molecules with multi hydroxyl functional groups in the same molecule is selected from the group consisting of maltitol, lactitol, maltotritol, ribitol, D-sorbitol, mannitol, dulcitol, iditol, D-(−)-Fructose, sorbitan, sucrose, ribose, Inositol, glucose, D-arabinose, L-arabinose, D-mannose, L-mannose, meso-erythritol, beta-lactose, arabinose, and combinations thereof.

17. The system of claim 15; wherein
the chemical mechanical polishing (CMP) composition comprises ceria-coated colloidal silica particles; the polysorbate-type surfactant selected from the group consisting of polyoxyethylenesorbitan monolaurate, polyoxyethylenesorbitan monopalmitate, polyoxyethylene sorbitan monostearate, polyoxyethylenesorbitan tristearate, polyoxyethylenesorbitan monooleate, polyoxyethylenesorbitan trioleate, and combinations thereof; the organic molecule with multi hydroxyl functional groups in the same molecule selected from the group consisting of D-sorbitol, Dulcitol, Maltitol, Lactitol, and combinations thereof; and water; and
the silicon oxide film is SiO₂ film.

18. The system of claim 15; wherein the chemical mechanical polishing (CMP) composition comprises at least one of
the biocide having active ingredients of 5-chloro-2-methyl-4-isothiazolin-3-one and 2-methyl- -isothiazolin-3-one; and
the pH adjusting agent selected from the group consisting of nitric acid, hydrochloric acid, sulfuric acid, phosphoric acid, other inorganic or organic acids, and mixtures thereof for acidic pH conditions; or selected from the group consisting of sodium hydride, potassium hydroxide, ammonium hydroxide, tetraalkyl ammonium hydroxide, organic quaternary ammonium hydroxide compounds, organic amines, and combinations thereof for alkaline pH conditions.

19. The system of claim 15; wherein the semiconductor substrate further comprises a silicon nitride surface; and removal selectivity of silicon oxide: silicon nitride is greater than one selected from the group consisting of 30, 40 and 50.

20. A method of predicating patterned wafer polishing performance of a chemical mechanical polishing composition for polishing the patterned wafer containing oxide and nitride films, comprising
determining down force DF1 (psi) for obtaining 2000 Å/min silicon oxide blanket wafer removal rate using a polishing composition;
determining silicon nitride blanket wafer removal rate at a down force of DF1+3.0 psi using the polishing composition;
calculating a DF Offset Selectivity of oxide: nitride films;
selecting the chemical additives having DF Offset Selectivity ≥25 or ≥35;
wherein the DF Offset Selectivity=2000 Å/min./SiN RR (Å/min.) at DF1+3 psi.

21. The method of claim 20, wherein the oxide film is silicon oxide film and nitride film is silicon nitride film.
